(19) United States
(12) Patent Application Publication
(10) Pub. No.: US 2015/0255308 A1
(43) Pub. Date: Sep. 10, 2015

(54) STRESS MODULATION OF SEMICONDUCTOR THIN FILM

(71) Applicant: NATIONAL TAIWAN UNIVERSITY, Taipei (TW)

(72) Inventors: CHING-FUH LIN, Taipei (TW); Yu-Wen CHENG, Taipei (TW); Yu-Zhong LIN, Taipei (TW)

(73) Assignee: NATIONAL TAIWAN UNIVERSITY, Taipei (TW)

(21) Appl. No.: 14/314,041

(22) Filed: Jun. 25, 2014

(30) Foreign Application Priority Data
Mar. 7, 2014 (TW) 103107794

(51) Int. Cl. H01L 21/324; C25D 7/12; H01L 21/02

(52) U.S. Cl. CPC H01L 21/3245; H01L 21/0254; H01L 21/0262; H01L 21/02631; C25D 7/12

(57) ABSTRACT

An embodiment discloses a method for modulating stress of a semiconductor film and comprises the steps of: providing a substrate; forming a semiconductor film on the substrate; performing an annealing treatment to the formed semiconductor film; and determining a residual stress of the semiconductor film at a certain compress strain, a certain tensile strain, or zero by controlling a temperature of the annealing treatment.

### CROSS-REFERENCE TO RELATED APPLICATIONS

The entire contents of Taiwan Patent Application No. 103107794, filed on Mar. 7, 2014, from which this application claims priority, are incorporated herein by reference.

### BACKGROUND OF THE INVENTION

1. Field of the Invention

The present invention relates to semiconductor films, and more particularly relates to stress modulation of a semiconductor film.

2. Description of Related Art

In recent years, gallium nitride (GaN) is III-V compound semiconductors having many superior characteristics to enable the community to invest a lot of resources to study its related technologies. The bandgap of gallium nitride is 3.39 eV at room temperature, belonging to ultraviolet light and being a direct bandgap. Gallium nitride also has a high excition binding energy, high electron and hole mobility, good thermal conductivity, and strong bonding strength. Due to these superior properties, gallium nitride has been widely used in Blu-ray, ultraviolet light emitting diodes (LED), semiconductor laser, optical sensor, high electron mobility transistor (HEMT), and high temperature and high-power devices.

In 1991, Nakamura used metal organic chemical vapor deposition (MOCVD) to first grow buffer layer on a sapphire substrate at low temperature, and then grow gallium nitride films at high temperature, so as to improve the lattice mismatch between the gallium nitride and the sapphire substrate. After that, gallium nitride-based semiconductor materials, such as blue emission light-emitting diodes and semiconductor lasers, had been widely used in semiconductors and optoelectronic transistor devices. In recent years, high quality of gallium nitride thin film can be grown by metal organic chemical vapor deposition or molecular beam epitaxy (MBE).

However, because the thermal expansion coefficient of gallium nitride is 33% less than that of the sapphire substrate, the gallium nitride film produces biaxial compressive residual stress during its growth. The presence of biaxial stress in the gallium nitride film will change the gap width, increase the defect concentration, and increase the leakage current.

Many researchers and groups proposed varied methods to obtain a gallium nitride thin film without stress. Akasaki group [1] used hydride vapor phase epitaxy (HYPE) to grow thick gallium nitride film. The thickness of the GaN film, however, needs to be sufficiently thick so as to fully release the residual stress. Li et al [2] used metal organic vapor phase method to grow gallium nitride film on a patterned sapphire substrate (PSS) and intended to release the stress by controlling the spacing and shape of the patterned sapphire substrate. However, the cost of patterned sapphire substrate is generally higher than conventional sapphire substrates. In addition, the shape and the spacing of patterned sapphire substrate are difficult to control. Basha group [3] used GaN/AlN/GaN/AlN multilayer film to release the residual stress; however, the multilayer film growth will cause the process more complex.

References: [1] Detchprohm T, Hiramatsu K, Itoh K, Akasaki I (1992) Relaxation process of the thermal strain in the GaN/α-Al2O3 heterostructure and determination of the intrinsic lattice constants of GaN free from the strain. Japanese journal of applied physics 31 (10B):L1454-L1456 [2] Wang M-T, Liao K-Y, Li Y-L (2011) Growth mechanism and strain variation of GaN material grown on patterned sapphire substrates with various pattern designs. Photonics Technology Letters, IEEE 23 (14):962-964 [3] Ravikiran L, Radhakrishnan K, Dharmarasu N, Agrawal M, Munawar Basha S (2013) Strain states of AlN/GaN-stress mitigating layer and their effect on GaN buffer layer grown by ammonia molecular beam epitaxy on 100-mm Si (111). J Appl Phys 114 (12):123503-123503-123506.

### SUMMARY OF THE INVENTION

In one general aspect, the present invention relates to a method to modulate a residual stress of a semiconductor film.

According to an embodiment of this invention, a method to modulate a residual stress of a semiconductor film comprising the steps of: providing a substrate; forming a semiconductor film on the substrate; annealing the semiconductor film; and modulating a residual stress of the semiconductor film to be a predetermined compressive strain, a predetermined tensile strain, or zero by controlling an annealing temperature of the annealing step.

In a preferred embodiment, the semiconductor film is a gallium nitride film.

In an embodiment, the residual stress of the semiconductor film is determined by the annealing temperature.

In an embodiment, when the annealing temperature is increased, the residual stress of the semiconductor film is transformed from a compressive strain to a tensile strain.

In an embodiment, the residual stress is zero when the annealing is controlled at a cretain annealing temperature.

### BRIEF DESCRIPTION OF THE DRAWINGS

FIGS. 1-3 show a method to modulate a residual stress of a semiconductor film according to a preferred embodiment of the present invention.

FIG. 4 is a Raman spectroscopy of a gallium nitride film of an embodiment after annealing at a certain annealing temperature.

FIG. 5 shows the relationship between residual stress of a gallium nitride film and annealing temperature according to the preferred embodiment of this invention.

### DETAILED DESCRIPTION OF THE PREFERRED EMBODIMENT

Reference will now be made in detail to those specific embodiments of the invention. Examples of these embodiments are illustrated in accompanying drawings. While the invention will be described in conjunction with these specific embodiments, it will be understood that it is not intended to limit the invention to these embodiments. On the contrary, it is intended to cover alternatives, modifications, and equivalents as may be included within the spirit and scope of the invention as defined by the appended claims. In the following description, numerous specific details are set forth in order to provide a thorough understanding of the present invention. The present invention may be practiced without some or all of these specific details. In other instances, well-known process operations and components are not described in detail in order not to unnecessarily obscure the present invention. While drawings are illustrated in detail, it is appreciated that the quantity of the disclosed components may be greater or less than that disclosed, except where expressly restricting the amount of the components. Wherever possible, the same or similar reference numbers are used in drawings and the description to refer to the same or like parts.

Embodiments of this invention provide a method to modulate a residual stress of a semiconductor film. In an embodiment, the semiconductor film produced by this invention can be stress-free.

According to a preferred embodiment of the present invention, a pulsed laser deposition is used to grow a semiconductor film, such as a gallium nitride film, on a substrate. According to the preferred embodiment of the present invention, a buffer layer is unnecessary to be firstly grown on the substrate and may be omitted from the procedure. Instead of using a buffer layer, the semiconductor film or the gallium nitride film can be directly grown on the substrate with a high temperature.

After the semiconductor film is grown, the semiconductor film or the gallium nitride film is annealed in a high-temperature furnace with a high temperature to relieve stress. Experimental results show that different residual stress can be obtained by controlling the annealing temperature at a range and by analytical procedure of the present invention. More particularly, by controlling the annealing temperature, the residual stress of the semiconductor film can be modulated and even a stress-free semiconductor film or gallium nitride film can be obtained.

Without limiting the scope of the present invention, the following describes the detail of the preferred embodiment of this invention.

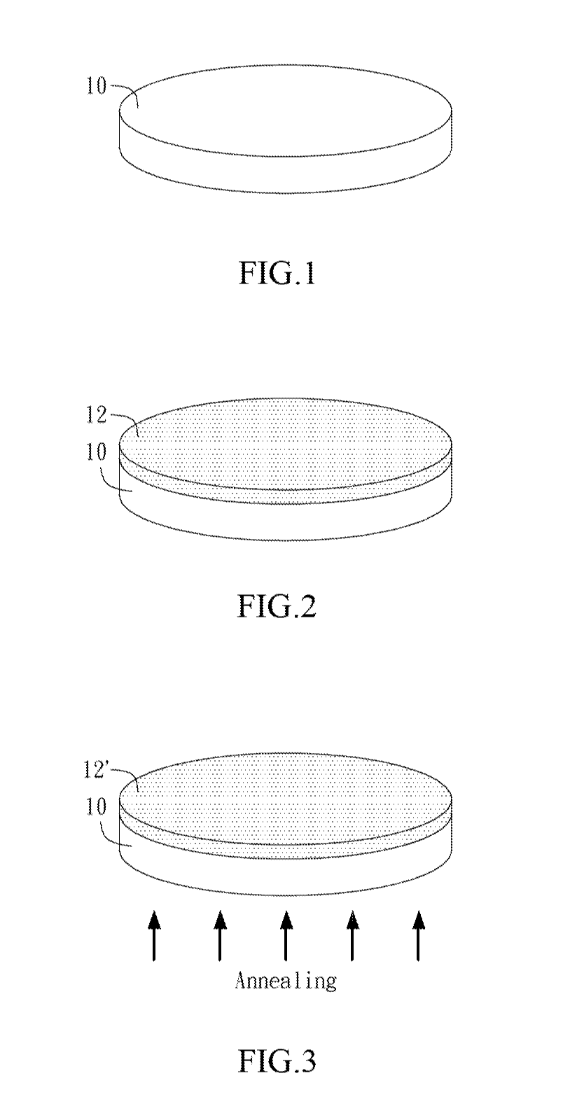

As shown in FIG. 1, a substrate 10, such as a sapphire substrate, is firstly provided. Then the substrate 10 is washed by deionized water, acetone, and methanol. After that, the substrate 10 is dried by a nitrogen spray gull.

As shown in FIG. 2, a proper system or procedure (such as a pulsed laser deposition system) is used to grow a semiconductor film 12 (such as a gallium nitride film) on the substrate 12. The detail is as follows. First, the washed substrate 10 is placed in a chamber of the pulsed laser deposition system. The pulsed laser deposition system employs a gallium nitride with purity 99.99% as the target. After the substrate 10 is placed within the chamber, a hydraulic motor and a turbine motor are used to exhaust gas out of the chamber and control the pressure to be under 10⁻⁶ torr. After that, the temperature of the substrate is elevated to a target temperature. When reaching the target temperature, a 99.9999% purity of nitrogen gas is injected into the chamber and the pressure of the chamber is controlled. After the gas pressure reaches balance, a set of optical lens is used to focus a KrF excimer laser with wavelength 248 nm into the chamber to collide the target, so as to grow a gallium nitride film on the substrate. The thickness of the gallium nitride film is between 300 nm and 400 nm.

As shown in FIG. 3, a post-annealing treatment is performed to the gallium nitride film. For example, the substrate 10 with the grown gallium nitride 12 is placed in a housing made of aluminum oxide, and the housing is placed into the high-temperature furnace. The pressure of the furnace is controlled below 1 torr and nitrogen gas with 99.99% purity is introduced into the furnace. After that, the pressure of the furnace is control at atmosphere. A recipe is set to control the substrate at an annealing temperature. The annealing temperature is maintained for 1 hour and then the substrate is cooled to room temperature.

In this embodiment, the annealing temperature is set at a range between 700° C. and 1100° C. At different annealing temperatures, such as 700, 800, 900, 923, 950, 975, 1000, and 1100° C., the characteristics of the gallium nitride film are analyzed by Raman spectrometer, x-ray diffraction, and scanning electron microscope (SEM).

Gallium nitride is a Wurzite structure at room temperature, belonging to space group C₆ᵥ⁴, and its first order scattering will generate eight phonon modes 2A₁+2E₁+2B₁+2E₂. The present invention employs Raman spectroscopy of the gallium nitride film to analyze the structure of the gallium nitride film at different annealing temperatures.

It is found that the gallium nitride film can be divided into three stages during the annealing procedure: (1) phase transformation, at the annealing temperature less than about 900° C., gallium nitride is transformed from a Rock Salt structure to a Wurzite structure; (2) stress transformation, at the annealing temperature between about 900° C. and 1000° C., the residual stress of gallium nitride is transformed; and (3) thermal decomposition, when the annealing temperature is greater than about 1000° C., gallium nitride is thermally decomposed.

For high quality gallium nitride film, the Raman spectroscopy of which has merely two peaks, E₂^{h} and A₁(LO), can be observed. Experimental results show that the intensity of E₂^{h} peak is significantly varied during the annealing temperature between 900° C. and 1000° C. It is speculated that the residual stress of the semiconductor film or the gallium nitride film can be calculated by the following formula:

Δω_{E}_{₂}=K_{E}_{₂}^{B}σ.

Wherein K_{E2}^{B} is biaxial stress coefficient and equals to −4.2 cm⁻¹ GPa⁻¹, Δω_{E2} is the difference between the intensity of E₂^{h} Raman shift of the gallium nitride film and the intensity of E₂^{h} Raman shift of a stress-free gallium nitride sample (typically with sufficient thickness to be stress-free), and σ is the residual stress of the gallium nitride film. The coefficient K_{E2}^{B} is negative, which means that the residual stress of the gallium nitride film is a compressive strain.

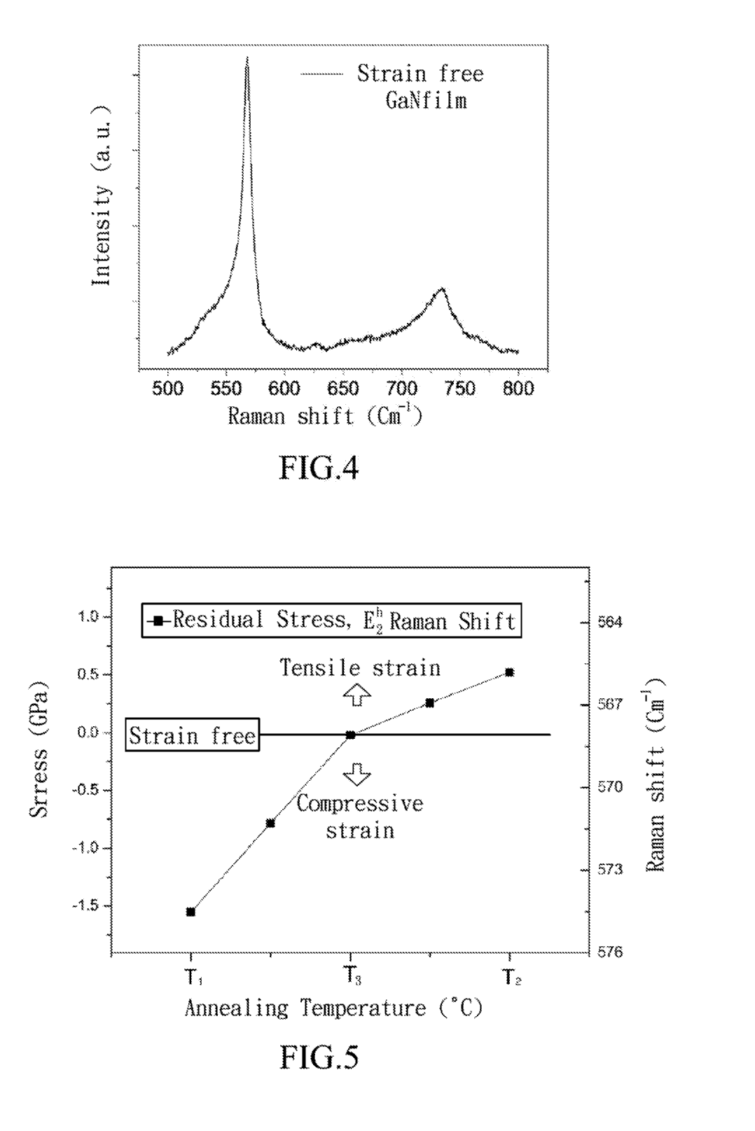

FIG. 4 shows a Raman spectroscopy of the produced gallium nitride film of this invention at a certain annealing temperature. In this embodiment, the certain annealing temperature is 950° C. As shown in FIG. 4, the E₂^{h} peak is at Raman shift 568.0 cm⁻¹, which is the same as the E₂^{h} peak of the Raman spectroscopy of the stress-free sample. This can prove that the residual stress of the produced gallium nitride is zero at the certain annealing temperature.

When the annealing temperature is gradually increased, the residual stress of the gallium nitride film is transformed to Tensile strain, which is positive.

FIG. 5 shows the residual stress, E₂^{h} Raman shift at different annealing temperatures. At low annealing temperature, the residual stress of gallium nitride film is compressive strain (e.g., annealing temperature T1). The compressive strain is gradually decreased as the annealing temperature is gradually increased, and finally the residual stress of gallium nitride film equals to zero (annealing temperature T3). The residual strain is gradually transformed to Tensile strain as the annealing temperature is further increased (e.g., annealing temperature T2). In this embodiment, T1 equals to 900° C., T2 equals to 1000° C., and T3 equals to 950° C.

As shown in FIGS. 4 and 5, since the relationship between the annealing temperature and the residual stress is found, the residual stress of gallium nitride film can be modulated to be a predetermined compressive strain, a predetermined tensile strain, or zero (stress-free) by controlling the annealing temperature.

Although the preferred embodiment is directed a method to find relationship between the residual stress of gallium nitride film grown on a sapphire substrate and the annealing temperature, the principle can be used to other systems, so as to find relationship between a residual stress of a semiconductor film and the annealing temperature. The other systems described herein may comprise one or more of different semiconductor materials, substrates, growing methods, film thicknesses, and/or annealing methods.

In an embodiment, the produced semiconductor film 12, such as gallium nitride film 12, is used as an epitaxial growth base to further growing at least a nitride semiconductor epitaxy layer and/or other epitaxy films on the semiconductor film 12.

In an embodiment, the substrate 10 is selected from the group consisting of a sapphire substrate, a silicon substrate, a quartz substrate, a gallium arsenic substrate, a metal substrate, and combinations thereof.

In an embodiment, wherein a thin-film consisting of zinc oxide film, aluminum oxide, gallium arsenic film, indium phosphide, and/or other materials is firstly grown on the substrate 10, then the semiconductor film 12 is grown on the thin-film.

In an embodiment, the semiconductor film 12 is formed by atomic layer deposition, electrochemical deposition, pulsed laser deposition, metal organic chemical vapor deposition, or molecular beam epitaxy.

In an embodiment, the semiconductor film or the gallium nitride film is directly grown on the above-mentioned thin-film at a high temperature, and a buffer layer is unnecessary to be firstly grown on the substrate or the thin-film.

In another embodiment, a buffer layer consisting of gallium nitride, aluminum nitride, gallium nitride/aluminum nitride, or zinc oxide is firstly formed on the thin-film or the substrate, then the semiconductor film 12 or the gallium nitride film 12 is grown on the buffer layer at the high temperature.

In an embodiment, the growing temperature of the semiconductor film 12 or the gallium nitride film 12 is between 30° C. and 1200° C.

In an embodiment, the semiconductor film 12 or the gallium nitride film 12 has a thickness between 0.1 μm and 10 μm.

In an embodiment, the annealing temperature of the semiconductor film 12 or the gallium nitride film 12 is between 30° C. and 1100° C.

In an embodiment, the annealing is performed by Furnace Annealing, High-temperature Furnace Annealing, Rapid Thermal Annealing, or Laser Annealing.

In an embodiment, nitrogen gas, helium gas, inert gas, and/or other gases is introduced into the chamber during the annealing procedure.

In an embodiment, a heating and/or cooling rate of the annealing procedure is at a range between 0.05° C./s and 50° C./s.

In an embodiment, the quality (crystallinity, flatness, etc.) of the semiconductor film 12 or the gallium nitride film 12 is promoted after the annealing procedure.

In an embodiment, the residual stress of the semiconductor film 12′ or the gallium nitride film 12′ is determined by the annealing temperature.

In an embodiment, when the annealing temperature is increased, the residual stress of the semiconductor film 12′ or the gallium nitride film 12′ is transformed from a compressive strain to a tensile strain.

In an embodiment, when the annealing is controlled at a certain annealing temperature, the residual stress of the semiconductor film 12′ or the gallium nitride film 12′ is zero (stress-free).

In an embodiment, the semiconductor film 12′ or gallium nitride film 12′ with specific compressive strain, tensile strain, or stress-free (zero) are applied in a piezoelectric device, a microelectromechanical system (MEMS), or a nanoelectromechanical system (NEMS).

In an embodiment, the semiconductor film 12′ or the gallium nitride film 12′ is used as an epitaxial growth base to further grow at least a nitride semiconductor layer or other epitaxy layers on the semiconductor film. In an embodiment, the nitride semiconductor layer or other epitaxy layers can be grown by atomic layer deposition, electrochemical deposition, pulsed laser deposition, metal organic chemical vapor deposition, or molecular beam epitaxy.

Accordingly, this invention provides a novel method to modulate a residual stress of a semiconductor film or a gallium nitride film. By controlling the annealing temperature, the residual stress of semiconductor film or gallium nitride film can be modulated. In particularly, a stress-free semiconductor film or gallium nitride film under certain annealing temperature can also be obtained.

Accordingly, an embodiment of this invention proposes a convenient way to deposit strain-free semiconductor film or gallium nitride film, solving the problems of residual stress remained at traditional grown gallium nitride films. The strain-free semiconductor film or gallium nitride film can be used to grow subsequent epitaxial layer(s). It is expected that the epitaxy layer grown on strain-free gallium nitride film has better performance than conventional one with residual stress. In addition, depending on different applications and purposes, it is able to control different annealing temperatures to produce semiconductor films or gallium nitride films with different stresses.

The intent accompanying this disclosure is to have each/all embodiments construed in conjunction with the knowledge of one skilled in the art to cover all modifications, variations, combinations, permutations, omissions, substitutions, alternatives, and equivalents of the embodiments, to the extent not mutually exclusive, as may fall within the spirit and scope of the invention. Corresponding or related structure and methods disclosed or referenced herein, and/or in any and all co-pending, abandoned or patented application(s) by any of the named inventor(s) or assignee(s) of this application and invention, are incorporated herein by reference in their entireties, wherein such incorporation includes corresponding or related structure (and modifications thereof) which may be, in whole or in part, (i) operable and/or constructed with, (ii) modified by one skilled in the art to be operable and/or constructed with, and/or (iii) implemented/made/used with or in combination with, any part(s) of the present invention according to this disclosure, that of the application and references cited therein, and the knowledge and judgment of one skilled in the art.

Conditional language, such as, among others, “can,” “could,” “might,” or “may,” unless specifically stated otherwise, or otherwise understood within the context as used, is generally intended to convey that embodiments include, and in other interpretations do not include, certain features, elements and/or steps. Thus, such conditional language is not generally intended to imply that features, elements and/or steps are in any way required for one or more embodiments, or interpretations thereof, or that one or more embodiments necessarily include logic for deciding, with or without user input or prompting, whether these features, elements and/or steps are included or are to be performed in any particular embodiment.

Although specific embodiments have been illustrated and described, it will be appreciated by those skilled in the art that various modifications may be made without departing from the scope of the present invention, which is intended to be limited solely by the appended claims.

What is claimed is:

1. A method to modulate a residual stress of a semiconductor film, comprising the steps of:
providing a substrate;
forming a semiconductor film on the substrate;
annealing the semiconductor film; and
modulating a residual stress of the semiconductor film to be a predetermined compressive strain, a predetermined tensile strain, or zero by controlling an annealing temperature of the annealing step.

2. The method as set forth in claim 1, wherein the semiconductor film is a gallium nitride film.

3. The method as set forth in claim 2, further comprising growing at least a nitride semiconductor epitaxy layer on the semiconductor film by using the semiconductor film as an epitaxial growth base.

4. The method as set forth in claim 1, wherein the substrate is selected from the group consisting of a sapphire substrate, a silicon substrate, a quartz substrate, a gallium arsenic substrate, a metal substrate, and combinations thereof.

5. The method as set forth in claim 4, wherein a thin-film consisting of zinc oxide film, aluminum oxide, gallium arsenic film, or indium phosphide is firstly grown on the substrate, then the semiconductor film is grown on the thin-film.

6. The method as set forth in claim 5, wherein the semiconductor film is formed by atomic layer deposition, electrochemical deposition, pulsed laser deposition, metal organic chemical vapor deposition, or molecular beam epitaxy.

7. The method as set forth in claim 5, wherein the semiconductor film is a gallium nitride film, and the gallium nitride film is directly grown on the thin-film at a high temperature

8. The method as set forth in claim 5, wherein the semiconductor film is a gallium nitride film, and a buffer layer consisting of gallium nitride, aluminum nitride, gallium nitride/aluminum nitride, or zinc oxide is firstly formed on the thin-film, then the gallium nitride film is grown on the buffer layer at the high temperature.

9. The method as set forth in claim 1, wherein the semiconductor film has a thickness between 0.1 μm and 10 μm.

10. The method as set forth in claim 1, wherein the annealing temperature is between 30° C. and 1100° C.

11. The method as set forth in claim 1, wherein the annealing step is performed by Furnace Annealing, High-temperature Furnace Annealing, Rapid Thermal Annealing, or Laser Annealing.

12. The method as set forth in claim 1, wherein the residual stress of the semiconductor film is determined by the annealing temperature.

13. The method as set forth in claim 1, when the annealing temperature is increased, the residual stress of the semiconductor film is transformed from a compressive strain to a tensile strain.

14. The method as set forth in claim 1, wherein the residual stress is zero when the annealing is controlled at a certain annealing temperature.

15. The method as set forth in claim 14, wherein the certain annealing temperature is obtained by comparing Raman spectroscopies of varies annealing temperatures and a Raman spectroscopy of a stress-free semiconductor sample composed of a material same as the semiconductor film.

16. The method as set forth in claim 1, wherein the residual stress of the semiconductor film is calculated by the following formula:
Δω_{E}_{₂}=K_{E}_{₂}^{B}σ, wherein K_{E2}^{B} is biaxial stress coefficient a, Δω_{E2} is the difference between an intensity of E₂^{h} Raman shift of the semiconductor film and the intensity of E₂^{h} Raman shift of a stress-free semiconductor sample, and σ is the residual stress of the semiconductor film.
